(19) United States
(12) Patent Application Publication
(10) Pub. No.: US 2025/0270480 A1
(43) Pub. Date: Aug. 28, 2025

(54) PROCESSING SOLUTION, METHOD FOR PROCESSING SEMICONDUCTOR SUBSTRATE, AND METHOD FOR MANUFACTURING SEMICONDUCTOR

(71) Applicant: TOKYO OHKA KOGYO CO., LTD., Kanagawa (JP)

(72) Inventor: Kenji SEKI, Kanagawa (JP)

(21) Appl. No.: 19/058,242

(22) Filed: Feb. 20, 2025

Related U.S. Application Data
(60) Provisional application No. 63/557,127, filed on Feb. 23, 2024.

(51) Int. Cl. C11D 7/08; C11D 7/06; C11D 7/32; C11D 7/50; H01L 21/02; H01L 21/311

(52) U.S. Cl. CPC C11D 7/08; C11D 7/06; C11D 7/3281; C11D 7/5022; H01L 21/02063; H01L 21/31144

(57) ABSTRACT

There are provided a processing solution, including (A) a compound capable of releasing a fluoride ion, (B) at least one selected from the group consisting of an ion of an alkali metal, an ion of an alkaline earth metal, and an ion of an element in Group III of the periodic table, and (C) an organic solvent; a method for processing a semiconductor substrate using the same; and a method for manufacturing a semiconductor using the same.

### TECHNICAL FIELD

The present invention relates to a processing solution, a method for processing a semiconductor substrate, and a method for manufacturing a semiconductor.

### BACKGROUND ART

In a wiring forming step, for example, a substrate, a metal wiring layer, and an interlayer insulating film which is silicon-based or the like are laminated in this order; a hard mask layer (HM layer) is formed on the interlayer insulating film; and the hard mask layer is etched to form a basic shape of a wiring pattern. As a material of the mask layer, for example, titanium, titanium-based alloys such as titanium nitride (TiN) and titanium oxide (TiOₓ (x represents a number.)), etc. are used.

Next, the interlayer insulating film is dry-etched using the etched HM layer as a mask layer to produce the wiring pattern such as metal wiring, etc.

Dry etching residues are conventionally removed by a cleaning processing. As a processing solution to remove dry etching residues, a processing solution containing a peroxide as a residue remover is used (for example, see Patent Document 1). Furthermore, a processing solution containing hydrogen fluoride to improve residue removal properties, etc. are used.

Patent Document 1: International Publication No. WO2016/076033

### SUMMARY OF THE INVENTION

The present inventor conducted detailed studies on processing solutions containing hydrogen fluoride, etc. and has found that these have room for improvement in achieving both removal of a titanium-based residue (residue containing titanium or a titanium-based alloy) and anticorrosion properties. For example, when a processing solution containing hydrogen fluoride or the like is used to remove residues, a problem such as damage to a metal layer to be protected may occur.

Furthermore, as a result of various studies on processing solutions other than those mentioned above, the present inventor has found that there is also still room for improvement in achieving both removal of a titanium-based residue and anticorrosion properties.

The present invention has been made in view of the above circumstances, and it is an object of the present invention to provide a processing solution that can efficiently remove a titanium-based residue and has excellent anticorrosion properties, a method for cleaning a semiconductor substrate using the same, and a method for manufacturing a semiconductor using the same.

As a result of intensive studies to achieve the above object, the present inventor has found a processing solution, including: (A) a compound capable of releasing a fluoride ion; (B) at least one selected from the group consisting of an ion of an alkali metal, an ion of an alkaline earth metal, and an ion of an element in Group III of the periodic table; and (C) an organic solvent, and has thus completed the present invention. That is, the present invention is as follows:
<1>

A processing solution, including: (A) a compound capable of releasing a fluoride ion; (B) at least one selected from the group consisting of an ion of an alkali metal, an ion of an alkaline earth metal, and an ion of an element in Group III of the periodic table; and (C) an organic solvent.
<2>

The processing solution according to <1>, in which a concentration of the component (B) is from 0.0005 to 0.5% by mass.
<3>

The processing solution according to <1>, further including: (D) an anticorrosive agent.
<4>

The processing solution according to <1>, further including: (E) water.
<5>

The processing solution according to <3>, including as the anticorrosive agent (D): a nitrogen-containing heterocyclic compound or a salt thereof.
<6>

The processing solution according to <4>, including as the organic solvent (C): at least one selected from the group consisting of an alcohol-based solvent, a glycol ester-based solvent, a sulfoxide-based solvent, a sulfone-based solvent, an amide-based solvent, a lactone-based solvent, an imidazolidinone-based solvent, a nitrile-based solvent, a ketone-based solvent, an ether-based solvent, an ester-based solvent, a pyrrolidone-based solvent, and a urea-based solvent.
<7>

The processing solution according to <1>, in which a content of the organic solvent (C) is from 0.1 to 99.999% by mass.
<8>

The processing solution according to <1>, in which a pH of the processing solution is from 2 to 6.
<9>

The processing solution according to <1>, in which the processing solution is a processing solution for a semiconductor substrate; the semiconductor substrate includes a substrate and a film formed on the substrate; and the film includes at least one selected from the group consisting of a silicon atom, a titanium atom, a cobalt atom, and an aluminum atom.
<10>

A method for processing a semiconductor substrate, the semiconductor substrate including a protective film, the method including: a step for removing an impurity from the semiconductor substrate by bringing the processing solution according to <1> into contact with the protective film.
<11>

A method for manufacturing a semiconductor, including: a step for preparing a semiconductor substrate including a substrate and a protective film provided on the substrate, a step for performing etching using the protective film, and a step for removing an impurity from the semiconductor substrate by bringing the processing solution according to <1> into contact with the semiconductor substrate after the etching.

According to the present invention, it is possible to provide a processing solution that can efficiently remove titanium-based residues and is excellent in anticorrosion properties, a method for cleaning a semiconductor substrate using the same, and a method for manufacturing a semiconductor using the same.

### BRIEF DESCRIPTION OF THE DRAWINGS

FIG. 1 is a cross-sectional view illustrating an example of an element (semiconductor substrate) to be cleaned after dry etching.

FIG. 2 is a conceptual diagram provided to explain an example of a processing solution according to the present embodiment.

FIG. 3 is a conceptual diagram provided to explain an example of a processing solution according to the present embodiment.

### DETAILED DESCRIPTION OF THE INVENTION

Hereinafter, an embodiment for carrying out the present invention (hereinafter simply referred to as “the present embodiment”) will be described in detail. The present embodiment below is an example for explaining the present invention, and it is not intended to limit the present invention to the following description. The present invention may be embodied with an appropriate modification within the scope of its gist. Furthermore, unless otherwise specified, the configurations and parameters disclosed in this specification can be combined in any manner. Additionally, unless otherwise specified, the upper and lower limits of the values disclosed in this specification can be combined in any manner.

In the drawings, the same elements are denoted by the same reference signs, and duplicate description will be omitted. In addition, the positional relationships such as top, bottom, left, and right are based on those illustrated in the drawings unless otherwise specified. Further, the dimensional ratios in the drawings are not limited to the illustrated ratios.

### Processing Solution

A processing solution according to the present embodiment is a processing solution, including: (A) a compound capable of releasing a fluoride ion; (B) at least one selected from the group consisting of an ion of an alkali metal, an ion of an alkaline earth metal, and an ion of an element in Group III of the periodic table; and (C) an organic solvent. By using the processing solution, a titanium-based residue can be efficiently removed and excellent anticorrosion properties can be achieved. Note that the titanium-based residue refers to a residue containing titanium or a titanium-based alloy. The titanium-based alloy refers to a form in which titanium, which is a metal, is bonded with a metal element other than titanium or a non-metal element. Although details will be described later, examples of the titanium-based alloy may include titanium nitride (TiN), titanium oxide (TiOₓ (x represents a number.), titanium oxynitride (TiON), titanium oxyfluoride (TiOF), etc.

The processing solution according to the present embodiment can be suitably used as a processing solution for removing an etching residue containing an inorganic substance. In that case, it can be suitably used as a processing solution for cleaning a semiconductor, etc. Note that the processing solution may also be called a cleaning solution, or the like.

The inorganic substance herein refers to a compound containing a metal, and examples thereof may include a metal, a metal oxide, a metal nitride, a metal chloride, a metal fluoride, etc. That is, the processing solution according to the present embodiment can efficiently remove an etching residue containing such an inorganic substance.

More specifically, the processing solution according to the present embodiment can efficiently remove a titanium-based residue (residue containing titanium or a titanium-based alloy) contained in a HM layer and another layer. In addition, the processing solution according to the present embodiment is also expected to efficiently remove an inorganic substance-containing residue that is derived from a metal wiring layer that contains one selected from the group consisting of a metal described below, and a metal oxide, a metal nitride, a metal chloride, and a metal fluoride thereof.

Examples of the metal may include one of metals selected from the group consisting of molybdenum (Mo), tungsten (W), ruthenium (Ru), copper (Cu), gold (Au), silver (Ag), iron (Fe), nickel (Ni), aluminum (Al), lead (Pb), zinc (Zn), tin (Sn), tantalum (Ta), magnesium (Mg), cobalt (Co), bismuth (Bi), cadmium (Cd), titanium (Ti), zirconium (Zr), antimony (Sb), manganese (Mn), beryllium (Be), chromium (Cr), germanium (Ge), vanadium (V), gallium (Ga), hafnium (Hf), indium (In), niobium (Nb), rhenium (Re), thallium (Tl), etc.; a metal oxide, a metal nitride, a metal chloride, a metal fluoride, etc. thereof; etc.

Examples of the metal oxide may include a metal oxide of the metal atoms described above. Specific examples of the metal oxide may include, but are not limited to, TiOₓ, TaOₓ, CuOₓ, CoOₓ, RuOₓ, AlOₓ, WOₓ, MoOₓ, AuOₓ, AgOₓ, FeOₓ, NiOₓ, etc. (Unless otherwise specified, x represents a number.).

Examples of the metal nitride may include a metal nitride of the metal atoms described above. Specific examples of the metal nitride may include, but are not limited to, TiNₓ, TaNₓ, CuNₓ, CoNₓ, RuNₓ, AlNₓ, WNₓ, MoNₓ, AuNₓ, AgNₓ, FeNₓ, NiNₓ, etc.

Examples of the metal chloride may include a metal chloride of the metal atoms described above. Specific examples of the metal chloride may include, but are not limited to, TiClₓ, TaClₓ, CuClₓ, CoClₓ, RuClₓ, AlClₓ, WClₓ, MoClₓ, AuClₓ, AgClₓ, FeClₓ, NiClₓ, etc.

Examples of the metal fluoride may include a metal fluoride of the metal atoms described above. Specific examples of the metal fluoride may include, but are not limited to, TiFₓ, TaFₓ, CuFₓ, CoFₓ, RuFₓ, AlFₓ, WFₓ, MoFₓ, AuFₓ, AgFₓ, FeFₓ, NiFₓ, etc.

The processing solution according to the present embodiment is suitable for removing an etching residue, and in particular it is more suitable for removing a dry etching residue. Usually, from the viewpoint of improving the yield of a semiconductor and preventing deterioration of electrical characteristics thereof, a dry etching residue is removed before the next step. For example, the processing solution according to the present embodiment is suitable for cleaning a semiconductor substrate after dry etching is performed in a wiring process.

For example, the processing solution according to the present embodiment can suitably remove a titanium-based residue (a residue containing titanium or a titanium-based alloy) derived from a HM layer and an etching residue containing an inorganic substance derived from a metal wiring layer, which are adhered in a wiring process. In particular, a titanium-based residue adhered on a semiconductor substrate after dry etching is a residue that has high wet resistance and is difficult to remove by cleaning processing. The processing solution according to the present embodiment can also efficiently clean such a residue. Although the reason that such effects are achieved is not certain, it is presumed as follows (Needless to say, the mechanism and effect according to the present embodiment are not limited to the description below.).

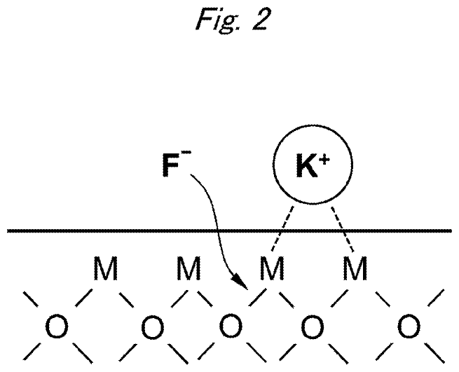

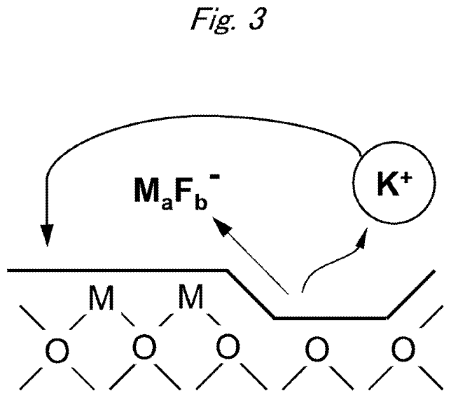

FIGS. 2 and 3 are schematic diagrams provided for explaining an example of the processing solution according to the present embodiment. In the figures, M schematically represents an ion of a metal such as titanium.

First, in dry etching in which a metal oxide, a metal nitride, etc. of, for example, titanium is used as a hard mask, there is a problem that a MOₓ (metal oxide)-based residue from the hard mask material is formed after dry etching. In this regard, according to the processing solution according to the present embodiment, (B) at least one selected from the group consisting of an ion of an alkali metal, an ion of an alkaline earth metal, and an ion of an element in Group III of the periodic table is adsorbed on a surface of a MOₓ metal residue (See FIG. 2. x in MOₓ indicates a number.) to loosen an inner bond inside the residue (See FIG. 2.).

Next, since the internal bond inside the residue is weakened, it becomes easier for a fluoride ion of the compound capable of releasing a fluoride ion (A) to make an attack (See “F⁻” in FIG. 2.). As a result, the dissolution reaction of the residue can be effectively promoted, so that the residue can be effectively removed (See “MₐF_{b}⁻” in FIG. 3. a and b each indicates a number.)

It is presumed that after the residue is removed, the ion of the component (B) is again adsorbed on another part of the residue surface and contributes to the promotion of the adsorption and the dissolution reaction of the residue again.

Thus, the component (B) is adsorbed on a surface of a residue and exerts a catalyst-like mechanism there, so that the dissolution reaction of the residue can be effectively promoted. As a result, it is presumed that the residue can be effectively removed without increasing the concentration of the component (A).

In this regard, conventionally, an attempt has been made to enhance removability of a residue of a titanium-based metal, etc. by increasing the concentration of hydrogen fluoride. However, a high concentration of hydrogen fluoride causes great damage to a metal layer. As a result, it becomes difficult to achieve both removability of a residue of a titanium-based metal and anticorrosion properties of a metal layer. A similar problem may occur in the case of silicon-based materials (for example, SiN, SiO₂, a low-k film (SiOC film, SiCOH film, etc.), ILD, etc.) that are susceptible to damage by hydrogen fluoride.

However, the processing solution according to the present embodiment is excellent in removability of a residue of a titanium-based metal by using the component (A) and the component (B) in combination without increasing the concentration of the component (A). Therefore, since damage to a metal layer and a silicon-based material can be suppressed, both removability of a residue of a titanium-based metal and anticorrosion properties of a metal layer and a silicon-based material can be achieved.

As for the concentrations (contents) of the component (A) and the component (B), suitable concentrations may be appropriately selected in consideration of the kind of the metal layer described above. For example, when a metal layer or a silicon-based material that is susceptible to damage by a fluoride ion is used, the concentration of the component (B) may be determined so that sufficient residue removal properties can be obtained even if the concentration of fluoride ions is low. On the other hand, when a metal layer or the like that is not susceptible to damage by a fluoride ion is used, the concentration of the fluoride ion may be somewhat high, and hence the concentration of the component (B) may be determined in consideration of it.

The above describes an example of the processing solution according to the present embodiment, and it goes without saying that the composition and usage of the processing solution according to the present embodiment are not limited to the above.

Hereinafter, the components of the processing solution according to the present embodiment will be described.

### (A) Compound Capable of Releasing a Fluoride Ion

Examples of the compound capable of releasing a fluoride ion may include hydrogen fluoride (HF), hexafluorosilicic acid, ammonium fluoride, tetramethylammonium fluoride (TMAF), etc. Among these, hydrogen fluoride is preferable. In the case of hydrogen fluoride, hydrofluoric acid (aqueous solution of hydrogen fluoride) may be added to produce the processing solution according to the present embodiment.

The component (A) may be used alone or in combination of two or more.

The content of the component (A) in the processing solution according to the present embodiment is not particularly limited, but is preferably from 0.001 to 10% by mass. The upper limit of the content of the component (A) is more preferably 5% by mass or less, even more preferably 18 by mass or less, and still even more preferably 0.5% by mass or less. The lower limit of the content of the component (A) is more preferably 0.002% by mass or more, even more preferably 0.003% by mass or more, still even more preferably 0.004% by mass or more, and further preferably 0.005% by mass or more. When the content of the component (A) is equal to or more than the above lower limit, removability of a titanium-based residue can be further enhanced in cleaning processing. On the other hand, when the content of the component (A) is equal to or less than the above upper limit value, damage to metal wiring, etc. can be further suppressed.

(B) At least one selected from the group consisting of an ion of an alkali metal, an ion of an alkaline earth metal, and an ion of an element in Group III of the periodic table

Examples of the ion of the alkali metal may include a lithium ion (Li⁺), a sodium ion (Na⁺), a potassium ion (K⁺), a rubidium ion (Rb⁺), a cesium ion (Cs⁺), a francium ion (Fr⁺), etc. Among these, a lithium ion, a sodium ion, and a potassium ion are preferable.

Examples of the ion of the alkaline earth metal may include a calcium ion (Ca²⁺), a barium ion (Ba²⁺), a strontium ion (Sr²⁺), a beryllium ion (Be²⁺), a magnesium ion (Mg²⁺), a radium ion (Ra²⁺), etc.

Examples of the ion of the element in Group III of the periodic table may include a scandium ion (Sc³⁺), an yttrium ion (Y³⁺), etc. Among these, a scandium ion (Sc³⁺) is preferable.

Among the above, as the component (B), an alkali metal ion is preferable, and a lithium ion, a sodium ion, and a potassium ion are more preferable.

The component (B) may be used alone or in combination of two or more.

The content of the component (B) in the processing solution according to the present embodiment is not particularly limited, but is preferably from 0.0005 to 0.5% by mass. The upper limit of the content of the component (B) is more preferably 0.3% by mass or less, even more preferably 0.2% by mass or less, and still even more preferably 0.1% by mass or less. The lower limit of the content of the component (B) is more preferably 0.001% by mass or more, even more preferably 0.002% by mass or more, still even more preferably 0.003% by mass or more, and further preferably 0.005% by mass or more. When the content of the component (B) is within the above range, it is possible to achieve both removability of a titanium-based residue and suppression of damage to a metal layer at higher levels. For example, since the processing solution according to the present embodiment can maintain removability of a titanium-based residue at a high level without increasing the concentration of the component (A), damage to a metal layer caused by the component (A) can be further effectively suppressed.

In the case of layers such as an interlayer insulating film, an etching stopper, a hard mask, etc. which use a silicon-based material, they tend to be susceptible to damage by the component (A) such as hydrogen fluoride, etc. However, according to the present embodiment, a titanium-based residue can be removed sufficiently effectively without necessarily increasing the concentration of the component (A) such as hydrogen fluoride, etc. Hence, damage to a metal layer that is susceptible to damage by the component (A) can be suppressed (However, the mechanism and effect according to the present embodiment are not limited thereto.).

### (C) Organic Solvent

The processing solution according to the present embodiment contains an organic solvent. The processing solution according to the present embodiment can be suitably used as an organic solvent-based processing solution (a processing solution in which an organic solvent content is higher than the water content, or a processing solution that does not contain water). As will be described later, the processing solution according to the present embodiment may contain not only an organic solvent but also water, but even in that case, it can be suitably used as an organic solvent-based processing solution containing more organic solvent than water.

Specific examples of the organic solvent are not particularly limited, and it is preferable that the organic solvent be at least one selected from the group consisting of an alcohol-based solvent, a glycol ester-based solvent, a sulfoxide-based solvent, a sulfone-based solvent, an amide-based solvent, a lactone-based solvent, an imidazolidinone-based solvent, a nitrile-based solvent, a ketone-based solvent, an ether-based solvent, an ester-based solvent, a pyrrolidone-based solvent, and a urea-based solvent. Furthermore, it is more preferable that the processing solution according to the present embodiment contain only at least one selected from the group consisting of an alcohol-based solvent, a glycol ester-based solvent, a sulfoxide-based solvent, a sulfone-based solvent, an amide-based solvent, a lactone-based solvent, an imidazolidinone-based solvent, a nitrile-based solvent, a ketone-based solvent, an ether-based solvent, an ester-based solvent, a pyrrolidone-based solvent, and a urea-based solvent and does not contain any kind of solvent other than these. Further, when the processing solution according to the present embodiment contains an organic solvent, it is preferable to use a water-soluble organic solvent from the viewpoint of water solubility of the processing solution.

Specific examples of the alcohol-based solvent may include aliphatic alcohols such as methanol, ethanol, modified ethanol, isopropanol, n-propanol, n-butanol, 3-methoxy-3-methyl-1-butanol, etc.; glycols such as ethylene glycol (also known as 1,2-ethanediol, monoethylene glycol), diethylene glycol (also known as 2,2′-oxydiethanol, diethyl glycol), propylene glycol (also known as propane-1,2-diol), dipropylene glycol, glycerin, 1,3-propanediol, 1,3-butanediol, 1,4-butanediol, furfuryl alcohol, hexylene glycol (also known as 2-methyl-2,4-pentanediol), etc.; and the like.

Specific examples of the glycol ester-based solvent may include ethylene-based glycol ether such as ethylene glycol monomethyl ether, ethylene glycol dimethyl ether, diethylene glycol monomethyl ether, diethylene glycol dimethyl ether, triethylene glycol monomethyl ether, triethylene glycol dimethyl ether, ethylene glycol monoethyl ether, ethylene glycol diethyl ether, ethylene glycol monobutyl ether, ethylene glycol dibutyl ether, diethylene glycol monobutyl ether, diethylene glycol dibutyl ether, triethylene glycol monobutyl ether, triethylene glycol dibutyl ether, ethylene glycol monohexyl ether, ethylene glycol dihexyl ether, diethylene glycol monohexyl ether, diethylene glycol dihexyl ether, ethylene glycol-phenyl ether, etc.; ethylene-based glycol ether acetates such as ethylene glycol monobutyl ether acetate, diethylene glycol monobutyl ether acetate, etc.; propylene-based glycol ether such as propylene glycol monomethyl ether (PGME), propylene glycol dimethyl ether, dipropylene glycol monomethyl ether (DPM), dipropylene glycol dimethyl ether, tripropylene glycol monomethyl ether, tripropylene glycol dimethyl ether, propylene glycol monoethyl ether, propylene glycol diethyl ether, dipropylene glycol monoethyl ether, dipropylene glycol diethyl ether, tripropylene glycol monoethyl ether, tripropylene glycol diethyl ether, propylene glycol monopropyl ether, propylene glycol dipropyl ether, dipropylene glycol monopropyl ether, dipropylene glycol dipropyl ether, propylene glycol monobutyl ether, propylene glycol dibutyl ether, dipropylene glycol monobutyl ether, dipropylene glycol dibutyl ether, tripropylene glycol monobutyl ether, tripropylene glycol dibutyl ether, propylene glycol phenyl ether, etc.; propylene-based glycol ether acetates such as propylene glycol methyl ether acetate, dipropylene glycol methyl ether acetate, propylene glycol diacetate, etc.; and the like.

Specific examples of the sulfoxide-based solvent may include dimethyl sulfoxide (DMSO), diethyl sulfoxide, dipropyl sulfoxide, diphenyl sulfoxide, thiophene, and the like.

Specific examples of the sulfone-based solvent may include dimethyl sulfone, diethyl sulfone, tetramethylene sulfone, dipropyl sulfone, sulfolane (also known as tetramethylene sulfone), 3-methylsulfolane, 2,4-dimethylsulfolane, 3,4-dimethylsulfolane, diphenylsulfolane, 3,4-diphenylmethylsulfolane, sulfolene, 3-methylsulfolene, 3-ethylsulfolene, and the like.

Specific examples of the amide-based solvent may include dimethylformamide (DMF), diethylformamide (DEF), dimethylacetamide (DMAc), N-methylpyrrolidine (MPD), hexamethylphosphate triamide (HMPA), and the like.

Specific examples of the lactone-based solvent may include γ-butyllactone, α-methyl-γ-butyrolactone, β-propiolactone, γ-valerolactone, δ-valerolactone, δ-caprolactone, ε-caprolactone, γ-laurolactone, hexanolactone, and the like.

Specific examples of the imidazolidinone-based solvent may include 2-imidazolidinone, 1,3-dimethyl-2-imidazolidinone, 1,3-diethyl-2-imidazolidinone, 1,3-dipropyl-2-imidazolidinone, 1,3-diisopropyl-2-imidazolidinone, and the like.

Specific examples of the nitrile-based solvent may include acetonitrile, propionitrile, valeronitrile, butyronitrile, and the like.

Specific examples of the ketone-based solvent may include acetone, methyl ethyl ketone (MEK), methyl isobutyl ketone (MIBK), diisobutyl ketone, cyclohexanone, diacetone alcohol, 1-hexanone, 2-hexanone, 4-heptanone, 2-heptanone (methylamyl ketone), 1-octanone, 2-octanone, 1-nonanone, 2-nonanone, acetylacetone, acetonyl acetone, phenylacetone, acetophenone, methylnaphthyl ketone, methylcyclohexanone, ionone, isophorone, propylene carbonate, diacetonyl alcohol, acetylcarbinol, and the like.

Specific examples of the ether-based solvent may include diisopropyl ether, 1,4-dioxane, methyl-tert-butyl ether (MTBE), dimethyl ether, diethyl ether, dipropyl ether, methylphenyl ether, and the like.

Specific examples of the ester-based solvent may include methyl acetate, ethyl acetate, butyl acetate, amyl acetate, propyl acetate, isopropyl acetate, methyl lactate, ethyl lactate, butyl lactate, ethyl methoxyacetate, ethyl ethoxyacetate, acetic acid 2-methoxybutyl (2-methoxybutyl acetate), acetic acid 3-methoxybutyl (3-methoxybutyl acetate), acetic acid 4-methoxybutyl (4-methoxybutyl acetate), acetic acid 3-methoxy-3-methylbutyl (3-methoxy-3-methylbutyl acetate), acetic acid 3-ethyl-3-methylbutyl (3-ethyl-3-methoxybutyl acetate), 4-methyl-4-methoxypentyl acetate, methyl formate, ethyl formate, propyl formate, butyl formate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, propyl-3-methoxypropionate, and the like.

Specific examples of the pyrrolidone-based solvent may include N-methylpyrrolidone (NMP), 2-pyrrolidone, N-vinyl-2-pyrrolidone, and the like.

Specific examples of the urea-based solvent may include 1,3-dimethylurea, 1,3-diethylurea, 1,3-dipropylurea, 1,3-diisopropylurea, tetramethylurea, tetraethylurea, tetrapropylurea, tetraisopropylurea, N,N-dimethylpropylene urea, and the like.

Among the above, the organic solvent is preferably a water-soluble organic solvent. Among the above specific examples, preferred examples of the water-soluble organic solvent may include alcohols such as isopropanol, ethanol, ethylene glycol, propylene glycol, glycerin, 1,3-propanediol, 1,3-butanediol, 1,4-butanediol, diethylene glycol, dipropylene glycol, furfuryl alcohol, hexylene glycol (also known as 2-methyl-2,4-pentanediol), etc.; glycol ester-based solvents such as diethylene glycol monobutyl ether, propylene glycol monomethyl ether, etc.; dimethyl sulfoxide; ethers such as ethylene glycol dimethyl ether, diethylene glycol dimethyl ether, triethylene glycol dimethyl ether, tetraethylene glycol dimethyl ether, propylene glycol dimethyl ether, etc.; morpholins such as N-methylmorpholine N-oxide, etc.; and the like. Among them, more preferred examples thereof may include hexylene glycol (also known as 2-methyl-2,4-pentanediol) and the like.

Among the above, as the organic solvent (C), alcohols are preferable, glycols are more preferable among alcohols, and hexylene glycol is even more preferable among glycols, from the viewpoint of compatibility with another component.

The organic solvent (C) may be used alone or in combination of two or more.

The content of the organic solvent (C) in the processing solution according to the present embodiment is not particularly limited, but is preferably from 0.1 to 99.999% by mass. When the content of the organic solvent (C) is high, it can be suitably used as a so-called organic solvent-based processing solution, and the content of the organic solvent can be selected depending on the application in consideration of the kind of a metal to be cleaned.

Furthermore, when water (E), which will be described later, is also used in combination, the ratio of the organic solvent content and the water content may be selected depending on the application in consideration of the kind of a metal to be cleaned. For example, when it is desired to reduce damage to a metal such as aluminum (that encompasses for example alumina, etc.), etc. using the processing solution according to the present embodiment, it is preferable to lower the water content. When it is desired to reduce damage to a metal (layer) such as aluminum, etc., it is preferable that the content of the organic solvent be higher than that of water. Thus, it may be possible to adjust the organic solvent content and the water content depending on the purpose in consideration of the kind of a metal to be cleaned.

The lower limit of the organic solvent content in the present embodiment is preferably 50% by mass or more, more preferably 60% by mass or more, even more preferably 70% by mass or more, still even more preferably 80% by mass or more, and further preferably 85% by mass or more. The upper limit of the organic solvent content may be 99.9% by mass or less, 99.5% by mass or less, or 99% by mass or less.

By using such an organic solvent, for example, it is possible to further improve anticorrosive properties of a layer containing a metal component such as cobalt, copper, tungsten, ruthenium, aluminum (that encompasses for example alumina, etc.), molybdenum, etc. as a main component (for example, a metal wiring layer, an etching stop layer, an interlayer insulating film, another functional layer, etc.). In other words, when using such a solvent, it is possible to more effectively reduce damage (film loss) to a layer containing aluminum (that encompasses for example alumina, etc.), cobalt, etc. without compromising removability of a titanium-based residue.

### (D) Anticorrosive Agent

The processing solution according to the present embodiment preferably contains an anticorrosive agent when it is desired to further improve anticorrosive properties for a metal layer. The processing solution according to the present embodiment is expected to have an advantage that even if an anticorrosive agent is used in combination, an anticorrosion effect of the anticorrosive agent is not reduced to maintain its high anticorrosion effect. As the anticorrosive agent, a suitable anticorrosive agent can be appropriately selected depending on the kind of a metal layer to be protected, etc.

Specific examples of the anticorrosive agent may include, but are not particularly limited to, at least one selected from the group consisting of a nitrogen-containing heterocyclic compound, a lactam ring-containing compound, a mercapto group-containing compound, an aliphatic amine compound, and salts thereof. Among these, the processing solution according to the present embodiment preferably contains a nitrogen-containing heterocyclic compound or a salt thereof.

Specific examples of the nitrogen-containing heterocyclic compound may include an imidazole ring-containing compound, a triazole ring-containing compound, a pyridine ring-containing compound, a pyrimidine ring-containing compound, a phenanthroline ring-containing compound, a tetrazole ring-containing compound, a pyrazole ring-containing compound, a purine ring-containing compound, and the like. Among them, the tetrazole ring-containing compound is preferable. By using the tetrazole ring-containing compound, for example, anticorrosion properties of a layer containing a metal component such as cobalt, copper, etc. as a main component (for example, a metal wiring layer, an etching stop layer, an interlayer insulating film, or another functional layer, etc.) can be further improved. That is, when the processing solution according to the present embodiment is used, damage (film loss) to a layer containing cobalt, copper, etc. can be more effectively reduced.

Specific examples of the imidazole ring-containing compound may include 1-decyl-3-methylimidazolium chloride, 2-ethyl-4-methylimidazole, 2-methylimidazole, 2-ethylimidazole, 2-isopropylimidazole, 2-propylimidazole, 2-butylimidazole, 4-methylimidazole, 2,4-dimethylimidazole, 2-undecylimidazole, 2-aminoimidazole, 2,2′-biimidazole, and the like.

Specific examples of the triazole ring-containing compound may include 1,2,4-triazole, 1,2,3-benzotriazole, 1,2,3-triazole, 3-amino-1H-1,2,4-triazole, 5-methyl-1H-benzotriazole (5MBTA), 1-hydroxybenzotriazole, 1-hydroxypropylbenzotriazole, 2,3-dicarboxypropylbenzotriazole, 4-hydroxybenzotriazole, 4-carboxyl-1H-benzotriazole, 4-carboxyl-1H-benzotriazole methyl ester, 4-carboxyl-1H-benzotriazole butyl ester, 4-carboxyl-1H-benzotriazole octyl ester, 5-hexylbenzotriazole, [1,2,3-benzotriazolyl-1-methyl][1,2,4-triazolyl-1-methyl][2-ethylhexyl]amine, tolyltriazole, naphthotriazole, bis[(1-benzotriazolyl)methyl]phosphonic acid, 3-aminotriazole, and the like.

Specific examples of the pyridine ring-containing compound may include 1H-1,2,3-triazolo[4,5-b]pyridine, 1,2,4-triazolo[4,3-a]pyridin-3(2H)-one, 3H-1,2,3-triazolo[4,5-b]pyridin-3-ol, 1-acetyl-1H-1,2,3-triazolo[4,5-b]pyridine, 3-aminopyridine, 4-aminopyridine, 3-hydroxypyridine, 4-hydroxypyridine, 2-acetamidopyridine, 4-pyrrolidinopyridine, 2-cyanopyridine, 2,2′-bipyridyl, 4,4′-dimethyl-2,2′-bipyridyl, 4,4′-di-tert-butyl-2,2′-bipyridyl, 4,4′-dinonyl-2,2′-bipyridyl, and the like.

Specific examples of the pyrimidine ring-containing compound may include pyrimidine, 1,2,4-triazolo[1,5-a]pyrimidine, 1,3,4,6,7,8-hexahydro-2H-pyrimido[1,2-a]pyrimidine, 1,3-diphenyl-pyrimidine-2,4,6-trione, 1,4,5,6-tetrahydropyrimidine, 2,4,5,6-tetraaminopyrimidine sulfate, 2,4,5-trihydroxypyrimidine, 2,4,6-triaminopyrimidine, 2,4,6-trichloropyrimidine, 2,4,6-trimethoxypyrimidine, 2,4,6-triphenylpyrimidine, 2,4-diamino-6-hydroxylpyrimidine, 2,4-diaminopyrimidine, 2-acetamidopyrimidine, 2-aminopyrimidine, 2-methyl-5,7-diphenyl-(1,2,4)triazolo(1,5-a)pyrimidine, 2-methylsulfanyl-5,7-diphenyl-(1,2,4)triazolo(1,5-a)pyrimidine, 2-methylsulfanyl-5,7-diphenyl-4,7-dihydro-(1,2,4)triazolo(1,5-a)pyrimidine, 4-aminopyrazolo[3,4-d]pyrimidine, and the like.

Specific examples of the phenanthroline ring-containing compound may include 1,10-phenanthroline and the like.

Specific examples of the tetrazole ring-containing compound may include 1H-tetrazole, 5-amino-1H-tetrazole (5am. Tet.), 5-methyl-1H-tetrazole, 5-phenyl-1H-tetrazole, 1-(2-diaminoethyl)-5-mercaptotetrazole, and the like.

Specific examples of the pyrazole ring-containing compound may include 3,5-dimethylpyrazole, 3-amino-5-methylpyrazole, 4-methylpyrazole, 3-amino-5-hydroxypyrazole, and the like.

Specific examples of the purine ring-containing compound may include purine and the like.

Specific examples of the lactam ring-containing compound may include polyvinylpyrrolidone (PVP) and the like.

Specific examples of the mercapto group-containing compound may include 1-thioglycerol, 3-(2-aminophenylthio)-2-hydroxypropyl mercaptan, 3-(2-hydroxyethylthio)-2-hydroxypropyl mercaptan, 2-mercaptopropionic acid, 3-mercaptopropionic acid, and the like.

Specific examples of the aliphatic amine compound may include an alkylamine, a dialkylamine, a trialkylamine, and the like.

The anticorrosive agent may also be a salt of the compounds described above. Specific examples of the salt may include, but are not particularly limited to, a sodium salt, a potassium salt, an ammonium salt, an alkylammonium salt (for example, a tetramethylammonium salt, etc.), and the like. It may also be a hydrate of the above compounds.

Furthermore, a preferred example of the anticorrosive agent from another viewpoint may for example be at least one selected from the group consisting of (a) a 5-membered ring-containing compound, (b) a 6-membered ring-containing compound, (c) a fused ring-containing compound, (d) an alkylammonium salt, and (e) a heterocyclic ring-containing alkylammonium salt.

As the 5-membered ring-containing compound (a), a nitrogen-containing 5-membered ring-containing compound is preferable. As specific examples of the 5-membered ring-containing compound, compounds having the following structures (compound (a1) to compound (a9)) are preferable (In the formulae, n represents a number.).

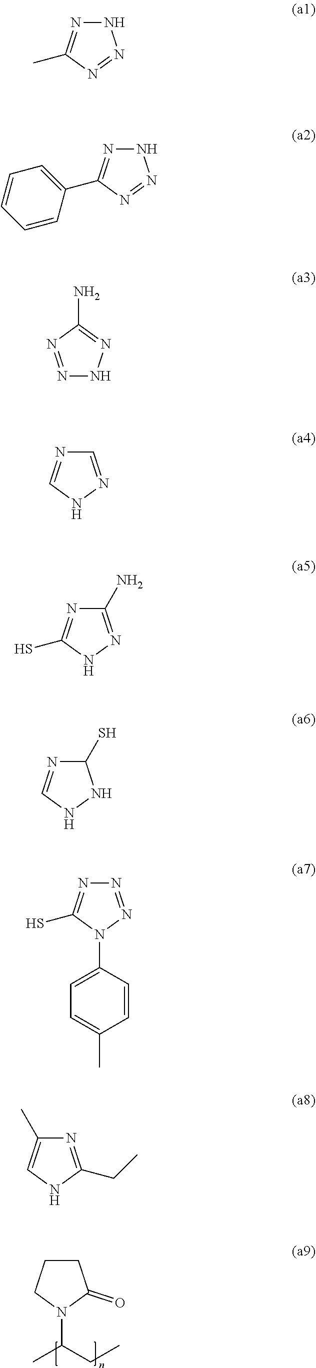

As the 6-membered ring-containing compound (b), a nitrogen-containing 6-membered ring-containing compound is preferable. As specific examples of the 6-membered ring-containing compound, compounds having the following structures (compound (b1) to compound (b6)) are preferable.

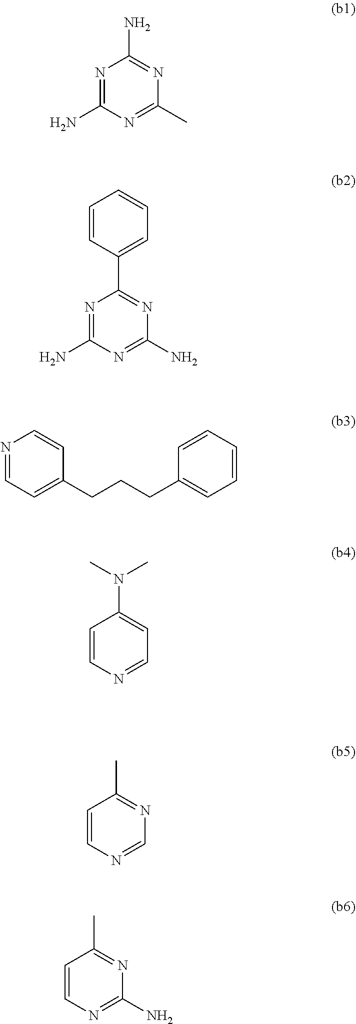

As the fused ring-containing compound (c), a nitrogen-containing fused ring-containing compound is preferable. As specific examples of the fused ring-containing compound, compounds having the following structures (compound (c1) to compound (c5)) are preferable.

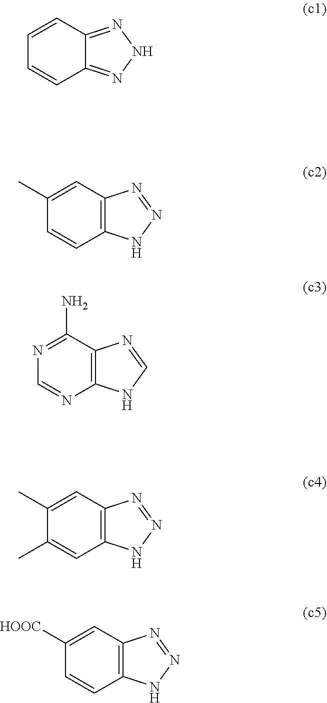

As the alkylammonium salt (d), compounds having the following structures (compound (d1) to compound (d6)) are preferable. Note that the following alkylammonium salts are each an alkylammonium salt that does not contain a heterocyclic ring.

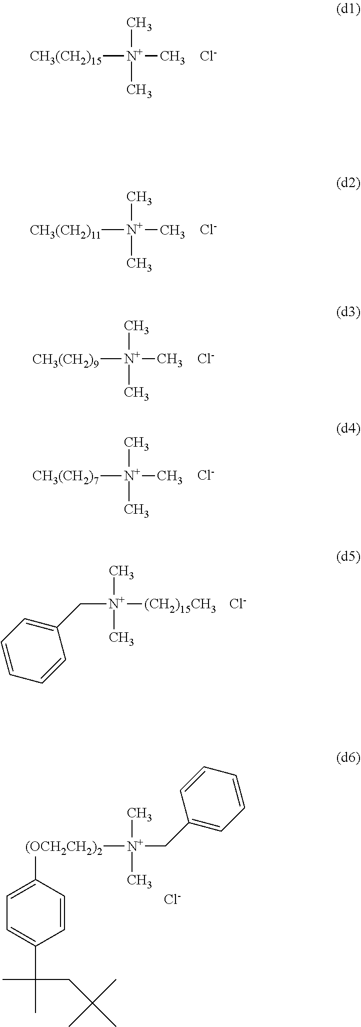

As the heterocyclic ring-containing alkylammonium salt (e), compounds having the following structures (compound (e2) to compound (e3)) are preferable.

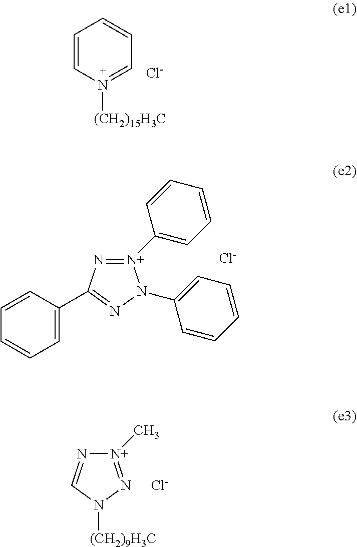

The anticorrosive agent may also be a salt of the compounds described above. Specific examples of the salt may include, but are not particularly limited to, a sodium salt, a potassium salt, an ammonium salt, an alkylammonium salt (for example, a tetramethylammonium salt, etc.), and the like. It may also be a hydrate of the above compounds.

The concentration of the anticorrosive agent in the processing solution according to the present embodiment is preferably from 0.0001 to 10% by mass. The upper limit of the concentration of the anticorrosive agent is more preferably 6% by mass or less, and even more preferably 3% by mass or less. The lower limit of the concentration of the anticorrosive agent is more preferably 0.001% by mass or more, even more preferably 0.01% by mass or more, and still even more preferably 0.1% by mass or more. When two or more anticorrosive agents are contained, the total amount is preferably within the above range.

The processing solution according to the present embodiment may or may not contain a component other than the above as necessary. Examples of such a component may include an anticorrosive agent, a pH adjuster, a surfactant, a solvent, etc. Further, the processing solution according to the present embodiment may contain a metal impurity, which will be described later, as long as an mechanism or effect thereof can be obtained.

### (E) Water

The processing solution according to the present embodiment may further contain water (E) as necessary. As water (E), for example, deionized water (DIW), etc. may be used from the viewpoint of being suitable for manufacturing a semiconductor device.

The content of the water in the processing solution according to the present embodiment is not particularly limited, but is preferably from 0.1 to 99.999% by mass. When the water content is high, it can be suitably used as a so-called aqueous processing solution, and the water content can also be selected depending on the application in consideration of the kind of a metal to be cleaned, etc.

For example, as described above, when it is desired to reduce damage to a metal (layer) such as aluminum, etc., it is preferable to lower the water content. On the other hand, when it is desired to improve etching effect of a metal (layer) such as aluminum, etc., it is preferable to increase the water content. The water content can be adjusted by, for example, adjusting the content of an organic solvent described later. For example, the water content can be lowered by increasing the organic solvent content. From this viewpoint, when a substrate to be processed has a layer containing aluminum such as alumina, etc., a processing solution with a low water content or a processing solution that does not contain water can be used. On the other hand, when a substrate to be processed does not have a layer containing aluminum such as alumina, etc., a processing solution containing water in moderation can be used from the viewpoint of costs, etc. Thus, it may be possible to choose and use either an organic solvent-based processing solution (a processing solution with the organic solvent content higher than the water content, or a processing solution that does not contain water) or an aqueous processing solution, depending on the purpose. From this viewpoint, one preferred example of the processing solution according to the present embodiment is an organic solvent-based processing solution (a processing solution with the organic solvent content higher than the water content, or a processing solution that does not contain water), for example.

Usually, when an organic solvent-based processing solution (a processing solution with the organic solvent content higher than the water content, or a processing solution that does not contain water) contains water, the lower limit of the content of water (E) is more preferably 0.1% by mass or more, even more preferably 1% by mass or more, and still even more preferably 5% by mass or more from the viewpoint of achieving both residue removal properties and anticorrosion properties at high levels. The upper limit of the content of the water (E) is more preferably less than 50% by mass, even more preferably 40% by mass or less, still even more preferably 30% by mass or less, further preferably 20% by mass or less, and further more preferably 15% by mass or less.

### pH Adjuster

The processing solution according to the present embodiment may contain a pH adjuster in order to adjust to a desired pH. As the pH adjuster, an inorganic acid, an organic acid, an organic basic compound, and an inorganic basic compound can be appropriately used. Examples of the pH adjuster may include methanesulfonic acid (MSA), acetic acid, sulfuric acid, phosphoric acid, hydrochloric acid, etc.

The pH of the processing solution according to the present embodiment is preferably from 2 to 6. The pH can be appropriately selected depending on the kind of a solvent (organic solvent, water) of the processing solution according to the present embodiment. For example, in the case of an organic solvent-based processing solution, the pH is more preferably from 2 to 5. In the case of an organic solvent-based processing solution, the upper limit value of the pH is even more preferably 4 or less. In the case of an aqueous processing solution, the pH is more preferably from 3 to 6. In the case of an aqueous processing solution, the lower limit value of the pH is even more preferably 4 or more.

### Buffer

The processing solution according to the present embodiment may contain a buffer. A buffer is a compound that has a mechanism of inhibiting a change in the pH of a processing solution. By containing a buffer, the pH of a processing solution can be efficiently controlled to a predetermined value. The buffer is not particularly limited as long as it is a compound having pH buffering ability.

Examples of the buffer may include Good's buffer. Examples of Good's buffer may include 2-cyclohexylaminoethanesulfonic acid (CHES), 3-cyclohexylaminopropanesulfonic acid (CAPS), N-tris(hydroxymethyl)methyl-3-aminopropanesulfonic acid (TAPS), 4-(cyclohexylamino)-1-butanesulfonic acid (CABS), tricine, bicine, 2-morpholinoethanesulfonic acid monohydrate (MES), bis(2-hydroxyethyl)aminotris(hydroxymethyl)methane (Bis-Tris), N-(2-acetamido)iminodiacetic acid (ADA), piperazine-1,4-bis(2-ethanesulfonic acid) (PIPES), N-(2-acetamido)-2-aminoethanesulfonic acid (ACES), 2-hydroxy-3-morpholinopropanesulfonic acid (MOPSO), N,N-bis(2-hydroxyethyl)-2-aminoethanesulfonic acid (BES), 3-morpholinopropanesulfonic acid (MOPS), N-tris(hydroxymethyl)methyl-2-aminoethanesulfonic acid (TES), 2-[4-(2-hydroxyethyl)-1-piperazinyl]ethanesulfonic acid (HEPES), 3-[N-tris(hydroxymethyl)methylamino]-2-hydroxypropanesulfonic acid (TAPSO), piperazine-1,4-bis(2-hydroxypropanesulfonic acid) (POPSO), 4-(2-hydroxyethyl)piperazine-1-(2-hydroxypropane-3-sulfonic acid) (HEPSO), 4-(2-hydroxyethyl)-1-piperazinepropanesulfonic acid (EPPS), and the like.

The buffer may be used alone or in combination of two or more. Alternatively, the processing solution according to the present embodiment may not contain a buffer.

### Surfactant

The processing solution according to the present embodiment may contain a surfactant for the purpose of adjusting wettability of the processing solution to a substrate, etc. Examples of the surfactant may include a nonionic surfactant, an anionic surfactant, a cationic surfactant, an amphoteric surfactant, etc.

Examples of the nonionic surfactant may include a polyalkylene oxide alkyl phenyl ether-based surfactant, a polyalkylene oxide alkyl ether-based surfactant, a block polymer-based surfactant composed of polyethylene oxide and polypropylene oxide, a polyoxyalkylene distyrenated phenyl ether-based surfactant, a polyalkylene tribenzyl phenyl ether-based surfactant, an acetylene polyalkylene oxide-based surfactant, and the like.

Examples of the anionic surfactant may include alkyl sulfonic acid, alkyl benzene sulfonic acid, alkyl naphthalene sulfonic acid, alkyl diphenyl ether sulfonic acid, fatty acid amide sulfonic acid, polyoxyethylene alkyl ether carboxylic acid, polyoxyethylene alkyl ether acetic acid, polyoxyethylene alkyl ether propionic acid, alkyl phosphonic acid, fatty acid, a salt thereof, and the like. Examples of the salt may include, but are not particularly limited to, a sodium salt, a potassium salt, an ammonium salt, an alkylammonium salt (for example, a tetramethylammonium salt, etc.), and the like.

Examples of the cationic surfactant may include an alkylpyridium-based surfactant, a quaternary ammonium salt-based surfactant, and the like.

Examples of the amphoteric surfactant may include a betaine-type surfactant, an amino acid-type surfactant, an imidazoline-type surfactant, an amine oxide-type surfactant, and the like.

These surfactants are generally commercially available. The surfactant may be used alone or in combination of two or more.

When the processing solution according to the present embodiment contains a surfactant, the content of the surfactant is not particularly limited and is preferably from 0.0001 to 5% by mass with respect to the total mass of the processing solution, for example. The lower limit of the content thereof is more preferably 0.0002% by mass or more, and even more preferably 0.002% by mass or more. The upper limit of the content thereof is more preferably 3% by mass or less, even more preferably 18 by mass or less, and still even more preferably 0.2% by mass or less.

The processing solution according to the present embodiment may not contain one or more kinds of surfactant selected from the group consisting of the nonionic surfactant, the anionic surfactant, the cationic surfactant, and the amphoteric surfactant, and may not contain one or more of the above compounds exemplified as these surfactants. The processing solution according to the present embodiment may not contain a surfactant.

### Impurity, etc.

The processing solution according to the present embodiment may contain a metal impurity containing at least one metal atom selected from the group consisting of a Fe atom, a Cr atom, a Ni atom, a Zn atom, a Ca atom, a Pb atom, etc., for example.

The total content of the metal atom in the processing solution according to the present embodiment is preferably 100 ppt by mass or less with respect to the total mass of the processing solution. The lower the lower limit value of the total content of the metal atom, the more preferable it is. For example, the lower limit value may be 0.001 ppt by mass or more. The total content of the metal atom may for example be from 0.001 ppt by mass to 100 ppt by mass. It is considered that the total content of the metal atom equal to or lower than the above preferred upper limit value improves defect suppression properties and residue suppression properties of the processing solution. It is considered that, with the total content of the metal atom equal to or higher than the above preferred lower limit value, the metal atom is less likely to be a free atom in the system and less likely to have a negative impact on the production yield of an entire object to be cleaned.

The content of the metal impurity can be adjusted by, for example, a purification process such as filtering or the like. The purification process such as filtering, etc. may be performed on a part or all of the raw materials before preparation of the processing solution, or may be performed after preparation of the processing solution.

The processing solution according to the present embodiment may contain, for example, an impurity derived from an organic substance (organic impurity). The total content of the organic impurity in the processing solution according to the present embodiment is preferably 5000 ppm by mass or less. The lower the lower limit of the total content of the organic impurity, the more preferable it is. For example, the lower limit may be 0.1 ppm by mass or more. The total content of the organic impurity may for example be from 0.1 ppm by mass to 5000 ppm by mass.

The processing solution according to the present embodiment may contain an object to be counted of such a size as counted by a light scattering liquid-borne particle counter, for example. The size of the object to be counted is, for example, 0.04 μm or more. The number of the object to be counted contained in the processing solution according to the present embodiment is, for example, 10000 or less per 1 mL of the processing solution, and the lower limit value thereof is, for example, 0.1 or more. It is considered that the number of the object to be counted in the processing solution within the above-described range improves a metal corrosion suppression effect and a defect suppression effect of the processing solution (However, the mechanism and effect according to the present embodiment are not limited thereto.).

The organic impurity and/or the object to be counted may be added to the processing solution or may be inevitably mixed in the processing solution in the manufacturing process of the processing solution. As non-limiting examples of the case that the organic impurity and/or the object to be counted is inevitably mixed in the processing solution in the manufacturing process of the processing solution, the organic impurity may be contained in a raw material (for example, an organic solvent) used for manufacturing the processing solution, or may be mixed in from an external environment in the manufacturing process of the processing solution (for example, contamination).

In the case that the object to be counted is added to the processing solution, the presence ratio may be adjusted for each specific size in consideration of surface roughness of an object to be cleaned, etc.

The processing solution according to the present embodiment can be used for various purposes. Among them, it is suitable as a processing solution for a semiconductor substrate that includes a substrate and a film formed on the substrate, the film including at least one selected from the group consisting of a silicon atom, a titanium atom, a cobalt atom, and an aluminum atom, from the viewpoint of effectively utilizing an effect and an advantage of the present embodiment. Furthermore, it is suitable for cleaning a semiconductor substrate on which a film containing a titanium atom is formed. Specifically, it is suitable for cleaning a semiconductor substrate on which a film containing at least one selected from the group consisting of titanium and a titanium-based alloy is formed. More specifically, a preferred example of the present embodiment is a processing solution for a semiconductor substrate that includes a substrate and a film formed on the substrate, the film containing at least one selected from the group consisting of titanium and a titanium alloy. A more preferred example is a semiconductor substrate that includes a substrate, a film containing at least one selected from the group consisting of titanium and a titanium alloy, and a film containing at least one selected from the group consisting of a silicon atom, a cobalt atom, and an aluminum atom (semiconductor substrate). For such a semiconductor substrate, the effects and advantages of excellent removability of a titanium-based residue and excellent protection of a metal layer to be protected of the present embodiment can be exhibited.

Hereinafter, an exemplary semiconductor substrate to which the processing solution according to the present embodiment can be used will be described.

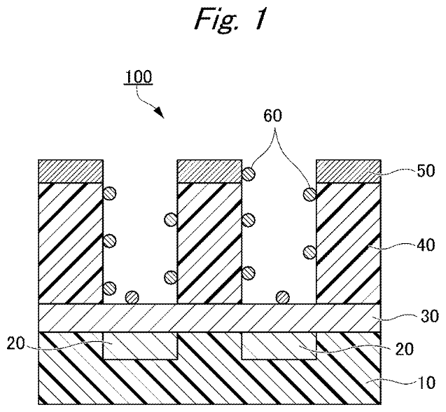

FIG. 1 is a cross-sectional view illustrating an exemplary element (semiconductor substrate) to be cleaned after dry etching.

A semiconductor element 100 illustrated in FIG. 1 includes a substrate 10, a metal wiring layer 20, an etching stop layer 30, and an interlayer insulating film 40, which are laminated in this order, and a hard mask layer (HM layer) 50 is formed on the interlayer insulating film 40 (substrate 10/metal wiring layer 20/etching stop layer 30/interlayer insulating film 40/HM layer 50).

The semiconductor element 100 has been subjected to dry etching in a wiring process. That is, it is in a state after the interlayer insulating film 40 is dry-etched using, as a mask, the HM layer 50 on which a basic shape of a wiring pattern is formed by dry etching. Dry etching residues 60 are adhered to side surfaces of the HM layer 50 and the interlayer insulating film 40. Although a case where etching is performed by dry etching is described here as an example, when etching is performed by wet etching, the resultant residue is a wet etching residue.

The metal wiring layer 20 is exposed to spaces in the interlayer insulating film 40 in the shape of the wiring pattern, and the dry etching residues 60 are also adhered.

As the substrate 10, for example, a substrate made of a material such as silicon, amorphous silicon, glass, or the like can be used.

One example of the metal wiring layer 20 may be a wiring layer containing one of metals such as molybdenum (Mo), tungsten (W), ruthenium (Ru), copper (Cu), iron (Fe), nickel (Ni), aluminum (Al), lead (Pb), zinc (Zn), tin (Sn), tantalum (Ta), magnesium (Mg), cobalt (Co), bismuth (Bi), cadmium (Cd), titanium (Ti), zirconium (Zr), antimony (Sb), manganese (Mn), beryllium (Be), chromium (Cr), germanium (Ge), vanadium (V), gallium (Ga), hafnium (Hf), indium (In), niobium (Nb), rhenium (Re), thallium (Tl), etc. and a metal oxide, a metal nitride, a metal chloride, a metal fluoride, etc. thereof.

Note that the metal wiring layer 20 is not limited to wiring and broadly includes those that act as a functional layer such as an electrode, an insulating layer, a low dielectric layer, and various conductor layers. It includes a layer formed by using the metals mentioned above and a metal oxide, a metal nitride, a metal chloride, a metal fluoride, etc. thereof. For example, as a silicon-based material, SiN, SiO₂, a low-k film (SiOC film, SiCOH film, etc.), ILD, etc. can be exemplified.

A material of the interlayer insulating film 40 may be any material as long as it has insulating properties. The material is not particularly limited, and a suitable material may be appropriately selected in consideration of a manufacturing condition, etc. Examples of the material contained in the interlayer insulating film 40 may include silicon-based materials such as SiO₂, SiN, SiOC, SiOCN, etc. For example, when the etching stop layer 30 is an etching stopper using alumina oxide or the like, part of the etching stop layer 30 located under the interlayer insulating film 40 is required to be protected from corrosion, and part thereof located on the metal wiring layer 20 is required to be removed. According to the processing solution according to the present embodiment, since both residue removal properties and anticorrosion properties can be achieved at high levels, it can also be expected to meet such requirements.

A material of the HM layer 50 may be any material as long as it acts as a protective film against etching. The material is not particularly limited, and a suitable material may be appropriately selected in consideration of a manufacturing condition, etc. As the HM layer 50, for example, a layer containing at least one selected from the group consisting of titanium and a titanium-based alloy can be suitably used. Since the processing solution according to the present embodiment is at least excellent in removability of a titanium-based residue, it is possible to efficiently remove a residue generated from the HM layer 50 using such a material (refer to the dry etching residues 60). As described above, as the titanium-based alloy, titanium-based materials such as titanium nitride (TiN), titanium oxide (TiOₓ (x represents a number.)), titanium oxynitride (TiON), titanium oxyfluoride (TiOF), etc. can be used.

The dry etching residues 60 are mainly Ti-containing residues that include a titanium-based material derived from the HM layer 50, but is not limited to such a residue. For example, the dry etching residues 60 encompass an etching residue containing the above-described inorganic substance, etc.

### Processing Method

The processing solution according to the present embodiment can be suitably used as a method for processing a semiconductor substrate. A method for processing a semiconductor substrate according to the present embodiment is a method for processing a semiconductor substrate having a protective film, the method including a step of removing an impurity from the semiconductor substrate by bringing the above-described processing solution into contact with the protective film. For example, in the case of the semiconductor element 100 (semiconductor substrate) illustrated in FIG. 1, the HM layer 50 corresponds to the protective film. Hereinafter, a case of cleaning the semiconductor element 100 illustrated in FIG. 1 will be described as an example.

The method for processing the semiconductor substrate according to the present embodiment is a step for cleaning the semiconductor element 100 after dry etching is performed in a wiring process by using the processing solution described above. A method for carrying out the processing is not particularly limited, and a known processing method can be used.

When the processing solution is brought into contact with the semiconductor element 100 to be cleaned, the processing solution may be diluted 2 to 2000 times to obtain a diluted solution, and a cleaning operation may then be performed using the diluted solution.

Examples of the cleaning operation may include a method of continuously discharging the processing solution on the semiconductor element 100 rotating at a constant speed (rotational application method), a method of immersing the semiconductor element 100 in the processing solution for a certain period of time (dipping method), a method of spraying the processing solution on a surface of the semiconductor element 100 (spraying method), and the like.

A temperature at which the cleaning processing is performed is not particularly limited, but the cleaning processing is preferably performed under the condition of 10 to 80° C. The lower limit of the temperature of the cleaning processing (the temperature of the processing solution) is more preferably 20° C. or more, and even more preferably 40° C. or more. The upper limit of the temperature of the cleaning processing (the temperature of the processing solution) is more preferably 75° C. or less, and even more preferably 70° C. or less. With the lower limit of the temperature of the cleaning processing within the range described above, removability of an etching residue can be further improved. With the upper limit of the temperature of the cleaning processing within the range described above, it is possible to more effectively suppress an unintentional change in the composition of the processing solution, and it is possible to clean more efficiently from the viewpoint of workability, safety, cost, etc.

Cleaning time can be appropriately selected so as to be sufficient for removing an etching residue, an impurity, etc. adhered on a surface of the semiconductor element 100. For example, the cleaning time is preferably from 10 seconds to 30 minutes. The lower limit of the cleaning time is more preferably 20 seconds or more, and even more preferably 30 seconds or more. The upper limit of the cleaning time is more preferably 15 minutes or less, even more preferably 10 minutes or less, and still even more preferably 5 minutes or less.

Since the processing solution according to the present embodiment is used for cleaning, in the semiconductor element 100 to which the dry etching residues 60 are adhered, the dry etching residues 60 derived from the HM layer 50, which is a protective film, can be well cleaned and removed while damage to the metal wiring layer 20 is suppressed. In particular, in the case of the HM layer 50 containing titanium and/or a titanium alloy, the processing solution according to the present embodiment is particularly suitable since it is excellent in removability of a titanium-based residue.

In addition, by using the processing solution according to the present embodiment, damage to various functional layers (metal wiring layer 20, etching stop layer 30, interlayer insulating film 40, etc.) other than the protective film can also be suppressed.

Furthermore, since the processing solution according to the present embodiment can achieve a practical level of cleaning effect without using conventional general-purpose hydroxylamine, etc., it can be expected to also provide an advantage that an semiconductor element, etc. can be manufactured more safely.

### Method for Manufacturing a Semiconductor

The processing solution according to the present embodiment and the cleaning method using the same can be suitably used as a method for manufacturing a semiconductor. A method for manufacturing a semiconductor according to the present embodiment is a method for manufacturing a semiconductor, including: (1) a step for preparing a semiconductor substrate including a substrate and a protective film provided on the substrate, (2) a step for performing etching using the protective film, and (3) a step for removing an impurity from the semiconductor substrate by bringing the above processing solution into contact with the semiconductor substrate after the etching. For example, in the case of the semiconductor element 100 (semiconductor substrate) illustrated in FIG. 1, the HM layer 50 corresponds to the protective film, as in the description of the cleaning method. Hereinafter, a case of cleaning the semiconductor element 100 illustrated in FIG. 1 will be described as an example.

### (1) Step for Preparing a Semiconductor Substrate Having a Substrate and a Protective Film Provided on the Substrate

In the step (1), a semiconductor substrate having a substrate and a protective film provided on the substrate is prepared. Although not illustrated, in the case of FIG. 1, a laminate before etching that has in this order a substrate 10, a metal wiring layer 20, an etching stop layer 30, an interlayer insulating film 40, and a hard mask layer (HM layer) 50 corresponding to the protective film is prepared (substrate 10/metal wiring layer 20/etching stop layer 30/interlayer insulating film 40/HM layer 50).

A method for sequentially laminating the substrate 10, the metal wiring layer 20, the etching stop layer 30, the interlayer insulating film 40, and the hard mask layer (HM layer) 50 corresponding to the protective film on the substrate 10 is not particularly limited, and a known method can be employed.

### (2) Step for Performing Etching Using the Protective Film

Subsequently, etching is performed using the protective film. For example, in the case of the interlayer insulating film 40 as an example, the part protected by the protective film is not etched, and the part not protected by the protective film is etched. In this manner, etching can be performed by using the protective film. An etching method is not particularly limited, may be wet etching or dry etching, but is preferably dry etching. Dry etching is advantageous from the viewpoint that metal wiring at nano level is possible and gas used can be controlled. In the case of dry etching, there is a concern that damage to the substrate 10, etc. is relatively large, but dry etching is also desirable from the viewpoint that such damage can be effectively suppressed by using the processing solution according to the present embodiment and an advantage of the present embodiment can be more effectively reflected.

In the case of dry etching, plasma can be used. Usually, when plasma etching is performed, there is a problem that the substrate 10 is susceptible to damage, or a problem that plasma etching generates a plasma etching residue and it is necessary to clean it with a processing solution. However, dry etching is also preferable in a point that such problems can be effectively suppressed by using the processing solution according to the present embodiment.

### (3) Step of Removing an Impurity from the Semiconductor Substrate by Bringing the Above Processing Solution into Contact with the Semiconductor Substrate after the Etching

As the step (3), the cleaning method described above can be used. Thereby, the semiconductor element 100 can be obtained. As necessary, a known post-processing may be performed after the cleaning.

As described above, the processing solution according to the present embodiment can be used, for example, as a processing solution for removing a residue generated in an etching step of a semiconductor, etc. In particular, the processing solution according to the present embodiment is suitable for removing a residue generated by dry etching. The processing solution according to the present embodiment has an advantage that it can efficiently remove a titanium-based residue and has excellent anticorrosion properties. For example, the processing solution according to the present embodiment can remove a residue generated when a substrate having a hard mask layer (HM layer) that contains at least one selected from the group consisting of titanium and a titanium-based alloy as a main component is dry etched more efficiently as compared with conventional ones.

Furthermore, in the cases of a processing solution containing hydrogen fluoride, a processing solution containing hydroxylamine, and a processing solution containing hydrogen peroxide, etc. that have been conventionally used, a problem such as large damage to a film to be protected (that is, a large amount of film loss) may occur, and it may be difficult to achieve both residue removal properties and anticorrosion properties. However, the processing solution according to the present embodiment can effectively suppress an occurrence of the problem. For example, it can be expected to reduce damage to a substrate, metal wiring, an etching stop layer, an interlayer insulating film and various other functional layers which contain as a metal component a silicon compound such as Si, SiN, etc., tungsten, molybdenum, ruthenium, copper, cobalt, etc. Therefore, it is also sufficiently possible to achieve a processing solution that is particularly excellent in removability of a titanium-based residue and in anticorrosion properties of a silicon compound and highly versatile metal materials such as tungsten, molybdenum, ruthenium, copper, cobalt, etc.

The processing solution according to the present embodiment can obtain a sufficient effect even if it does not contain hydrogen peroxide. The processing solution according to the present embodiment can obtain a sufficient effect even if it does not contain hydroxylamine. The processing solution according to the present embodiment can obtain a sufficient effect even if it does not contain tetramethylammonium hydroxide (TMAH) and/or tetraethylammonium hydroxide (TEAH). From these viewpoints, the processing solution according to the present embodiment may be a processing solution that does not contain hydrogen peroxide. The processing solution according to the present embodiment may be a processing solution that does not contain hydroxylamine. The processing solution according to the present embodiment may be a processing solution that does not contain tetramethylammonium hydroxide (TMAH). The processing solution according to the present embodiment may be a processing solution that does not contain tetraethylammonium hydroxide (TEAH).

### EXAMPLES

The present invention will be described in more detail with reference to the following Examples and Comparative examples, but the present invention is not limited in any way to the following Examples.

### 1. Test 1

### 1-1. Preparation of Processing Solution

### Comparative Examples 1-1 to 1-5, Example 1-1

Processing solutions having the compositions given in Table 1 were prepared.

For example, Example 1-1 was a solvent-based processing solution containing only 0.01% by mass of hydrogen fluoride (HF), 0.015% by mass of potassium hydroxide (KOH), 0.4% by mass of 5-methyl-1H-benzotriazole (5MBTA), 0.026% by mass of methanesulfonic acid (MSA), 9.55% by mass of water (deionized water: DIW), and 90% by mass of hexylene glycol (HG) as the balance. The processing solution of Example 1-1 had a pH of 3.43 and a potassium ion (K⁺) concentration of 0.015% by mass. 5MBTA was used as an anticorrosive agent expected to have an anticorrosion effect, and MSA was used as a pH adjuster to a desired pH value of the processing solution.

For example, Comparative example 1-1 was a solvent-based processing solution containing 0.01% by mass of hydrogen fluoride (HF), 0.4% by mass of 5MBTA, 9.59% by mass of water, and 90% by mass of hexylene glycol (HG) as the balance. The processing solution of Comparative example 1-1 had a pH of 4.31 and a potassium ion concentration of 0% by mass. In Comparative example 1-1, MSA was not added since there was no need to adjust the pH.

### Method for Measuring the pH of Processing Solution

The pH of each of the processing solutions was measured using a pH/ORP meter (portable pH meter “ORION STAR A324”, manufactured by Thermo Scientific) under a temperature condition of 22° C.

### 1-2. Evaluation of Removability of Titanium-Based Residue (Residue Removal Properties)

The removability of titanium-based residues of Examples and Comparative examples was evaluated by the following method (evaluation based on time to remove residues).

First, a laminate (a substrate having a film) was prepared by a CVD method, in which a third layer (a metal wiring layer, cobalt), an etching stop layer (aluminum oxide), a second layer (an interlayer insulating film), and a first layer (a metal hard mask layer, titanium oxide: film thickness of 50 nm) are laminated in this order on a substrate (12-inch silicon substrate) in cross-sectional view. (Substrate/third layer/etching stop layer/second layer/first layer). The laminate was cut into 2 cm×2 cm in top view to prepare samples for testing.

Subsequently, plasma etching was performed on the obtained samples (laminates) using the first layer as a mask to etch the second layer until a surface of the third layer was exposed to form holes (diameter/shape: 40 nm, hole-like shape), thereby preparing substrates for measurement having the configuration illustrated in FIG. 1 (samples after etching) (see FIG. 1).

Then, the samples after etching (substrates for measurement) were cleaned. The cleaning was performed by the following method. First, the processing solutions of Examples and Comparative examples were heated to 58° C. Subsequently, the samples after etching were immersed in the respective processing solutions of Examples and Comparative examples at 58° C. Thereafter, the samples were taken out from the processing solutions, cleaned with isopropyl alcohol, and dried by nitrogen blowing. Then, the amounts of residues remaining on the samples were confirmed with a scanning electron microscope (SEM, imaging magnification: 100k ×, device name “SU-8220”, manufactured by Hitachi High-Technologies). Specifically, the residue removal properties were evaluated by measuring time required until no etching residue (titanium-based residue) was observed on a hole wall surface. It was determined that the shorter the time to remove residues, the better the residue removal properties.

### 1-3. Evaluation of Anticorrosion Properties

The anticorrosion properties of Examples and Comparative examples were evaluated by the following method.

First, laminates having the respective metal layers (substrates each having a film) were prepared as described below.
A laminate having a SiN metal layer (film thickness: 20 nm) formed on a substrate (12-inch silicon substrate) was prepared by a CVD method.
A laminate having a Co metal layer (film thickness: 20 nm) formed on a substrate (12-inch silicon substrate) was prepared by the CVD method.
A laminate having an Al203 metal layer (film thickness: 20 nm) formed on a substrate (12-inch silicon substrate) was prepared by the CVD method.

Subsequently, the obtained laminates (substrates each having a film) were cut into 2 cm×2 cm in top view to obtain samples for testing (wafer coupons). Then, 80 mL of each of the processing solutions of Examples and Comparative examples was poured into a 100 mL cup. The samples were placed and immersed in the respective processing solutions under the immersion conditions of immersion temperature of 58° C. and predetermined immersion time. The immersion time was 30 minutes for the SiN metal layer laminate, 10 minutes for the Co metal layer laminate, and 5 minutes for the Al₂O₃ metal layer laminate. During the immersion, the processing solutions were stirred at 300 rpm. After the immersion, the samples were taken out from the processing solutions, washed with water at room temperature for 30 seconds, and dried by nitrogen blowing.

Then, by measuring the etching rate (Å/min), the film loss after processing was evaluated. In the case of the metal layers of SiN, Co, and Al₂O₃, it was determined that the lower the etching rate of the metal layer, the more the damage to the metal layer was avoided.

Table 1 indicates the compositions and evaluation results of the processing solutions of Example and Comparative examples.

TABLE 1

| | | Comparative | Comparative | Comparative | Comparative | Comparativel | |
|---|---|---|---|---|---|---|---|
| | | example | example | example | example | example | Example |
| | | 1-1 | 1-2 | 1-3 | 1-4 | 1-5 | 1-1 |
| Composition | HF | 0.01 | 0.1 | 0.2 | 0.3 | 0.01 | 0.01 |
| [wt %] | 5MBTA | 0.4 | 0.4 | 0.4 | 0.4 | 0.4 | 0.4 |
| | HG | 90 | 90 | 90 | 90 | 90 | 90 |
| | MSA | — | — | — | — | 0.04 | 0.026 |
| | KOH | — | — | — | — | — | 0.015 |
| | DIW | 9.59 | 9.5 | 9.4 | 9.3 | 9.55 | 9.55 |
| pH | | 4.31 | 3.42 | 3.4 | 3.35 | 3,3 | 3.43 |
| TiOx residue removal time | | >10 min | >10 min | <3 min | <3 min | >10 min | <3 min |
| Etching rate | SiN | 0.6 | 3.5 | 5.7 | 6.9 | 0.1 | 1.6 |
| [Å /min] | Co | 0.7 | 3.5 | 3.8 | 9.7 | 4.1 | 1.5 |
| | Al₂O₃ | 12.8 | 43.7 | 75.3 | 147 | 16.8 | 36.5 |

HF: hydrogen fluoride,
5MBTA: 5-methyl-1H-benzotriazole,
HG: hexylene glycol,
MSA: methanesulfonic acid,
KOH: potassium hydroxide,
DIW: deionized water

As indicated in Table 1, it was at least confirmed that Example 1-1 in Table 1 sufficiently removed the titanium-based residues and sufficiently avoided damage to the metals whose etching rate was measured.

### 2. Test 2

### 2-1. Preparation of Processing Solution

### Comparative Examples 2-1 to 2-3, Examples 2-1 to 2-3

Processing solutions having the compositions given in Table 2 were prepared.

For example, Example 2-1 was an organic solvent-based processing solution containing only 0.01% by mass of hydrogen fluoride (HF), 0.02% by mass of potassium chloride (KCl), 0.4% by mass of 5-methyl-1H-benzotriazole (5MBTA), 9.57% by mass of water (deionized water: DIW), and 90% by mass of hexylene glycol (HG) as the balance. The processing solution of Example 2-1 had a pH value of 3.4 and a potassium ion (K+) concentration of 0.02% by mass. 5MBTA was used as an anticorrosive agent expected to have an anticorrosion effect.

For example, Comparative example 2-2 was an aqueous processing solution containing 0.01% by mass of hydrogen fluoride (HF), 0.4% by mass of 5MBTA, and 99.59% by mass of water as the balance. The processing solution of Comparative example 2-2 had a pH value of 3 and a potassium ion (K+) concentration of 0% by mass.

### Method for Measuring the pH of Processing Solution

The pH of each of the processing solutions was measured by the same method as in “1. Test 1” above.

### 2-2. Evaluation of Removability of Titanium-Based Residue (Etching Residue Removal Properties)

Samples for testing were prepared in the same manner as in “1-2. Evaluation of removability of titanium-based residue (residue removal properties)” in “1. Test 1” above. Etching was performed in the same manner as in “1-2. Evaluation of removability of titanium-based residue (residue removal properties)” to obtain etching samples (substrates for measurement).

Then, the samples after etching (substrates for measurement) were cleaned. The cleaning was performed by the following method. First, the processing solutions of Examples and Comparative examples were heated to 58° C. Subsequently, the samples after etching were immersed in the respective processing solutions of Examples and Comparative examples at 58° C. for 3 minutes. Thereafter, the samples were taken out from the processing solutions, cleaned with isopropyl alcohol, and dried by nitrogen blowing. Then, the amounts of residues remaining on the samples were confirmed with the scanning electron microscope (SEM, imaging magnification: 100k ×, device name “SU-8220”, manufactured by Hitachi High-Technologies). Specifically, the residue removal properties were evaluated by confirming whether or not there are any etching residues (titanium-based residues) on a hole wall surface. The residue removal properties were evaluated based on the following criteria. Note that corrosion to a degree that would cause a practical problem was not observed on any of the metal layers of the substrates for measurement of Examples.

The criteria for determination of the residue removal properties are as follows.
A: As a result of confirmation performed after immersion with SEM under the same conditions, it was confirmed that 95% or more of the residues that were confirmed with SEM before immersion had been removed.
B: As a result of confirmation performed after immersion with SEM under the same conditions, it was confirmed that 85% or more and less than 95% of the residues that were confirmed with SEM before immersion had been removed.
C: As a result of confirmation performed after immersion with SEM under the same conditions, it was confirmed that 80% or more and less than 85% of the residues that were confirmed with SEM before immersion had been removed.
D: As a result of confirmation performed after immersion with SEM under the same conditions, it was confirmed that only less than 80% of the residues that were confirmed with SEM before immersion had been removed.

### 2-3. Evaluation of Anticorrosion Properties (Film Loss)

Samples for testing were prepared in the same manner as in “1-3. Evaluation of anticorrosion properties” in “1. Test 1” above. The anticorrosion properties were evaluated by measuring the etching rates of SiN, Co, and Al₂O₃. It was determined that the lower the etching rate of the metal layer, the more the damage to the metal layer was avoided.

Table 2 indicates the compositions and evaluation results of the processing solutions of Examples.

TABLE 2

| | | Comparative | Comparative | Comparative | | | |
|---|---|---|---|---|---|---|---|
| | | example | example | example | Example | Example | Example |
| | | 2-1 | 2-2 | 2-3 | 2-1 | 2-2 | 2-3 |
| Composition | HF (wt %) | 0.1 | 0.01 | 0.01 | 0.01 | 0.01 | 0.01 |
| [wt %] | KCl (wt %) | — | — | — | 0.02 | 0.04 | 0.1 |
| | 5MBTA (wt %) | — | 0.4 | 0.4 | 0.4 | 0.4 | 0.4 |
| | HG (wt %) | — | — | 90 | 90 | 90 | 90 |
| | DIW (wt %) | 99.9 | 99.59 | 9.59 | 9.57 | 9.55 | 9.49 |
| | pH | 2.9 | 3 | 4.1 | 3.4 | 3.3 | 3.2~3.3 |
| TiOx residue | 58° C.-3 min | A | A | D | B | B | A |
| removability | | | | | | | |
| Etching rate | SiN | 3.7 | 4.8 | 0.3 | 1.5 | 1,6 | 1.7 |
| [Å/min] | Co | 356 | 4.4 | 0.7 | 0.5 | 1.4 | 2.2 |
| | Al₂O₃ | >200 | 200 | 20 | 31 | 31 | 42 |

HF: hydrogen fluoride,
KCl: potassium chloride,
5MBTA: 5-methyl-1H-benzotriazole,
HG: hexylene glycol,
DIW: deionized water

As indicated in Table 2, it was at least confirmed that Examples in Table 2 sufficiently removed the titanium-based residues and sufficiently avoided damage to the metals whose etching rate was measured.

### 3. Test 3

### 3-1. Preparation of Processing Solution

### Comparative Examples 3-1 to 3-2, 4-1 to 4-2, Examples 3-1 to 3-7, 4-1 to 4-4

Processing solutions having the compositions given in Tables 3 and 4 were prepared.

### Method for Measuring the pH of Processing Solution

The pH of each of the processing solutions was measured by the same method as in “1. Test 1” above.

### 3-2. Evaluation of Removability of Titanium-Based Residue (Residue Removal Properties)

3-2-1. As a first evaluation method, the residue removability of titanium-based residues was evaluated by the following method.

Samples for testing were prepared in the same manner as in “1-2. Evaluation of removability of titanium-based residue (residue removal properties)” in “1. Test 1” above. Etching was performed in the same manner as in “1-2. Evaluation of removability of titanium-based residue (residue removal properties)” to obtain etching samples (substrates for measurement).

Then, the samples after etching (substrates for measurement) were cleaned. The cleaning was performed by the following method. First, the processing solutions of Examples and Comparative examples were heated to 58° C. Subsequently, the samples after etching were immersed in the respective processing solutions of Examples and Comparative examples at 58° C. (In the case of Table 3, the immersion time was 4 minutes, and in the case of Table 4, the immersion time was 5 minutes.). Thereafter, the samples were taken out from the processing solutions, cleaned with isopropyl alcohol, and dried by nitrogen blowing. Then, the amounts of residues remaining on the samples was confirmed with the scanning electron microscope (SEM, imaging magnification: 100k ×, device name “SU-8220”, manufactured by Hitachi High-Technologies). Specifically, the residue removal properties were evaluated by confirming whether or not there are any etching residues (titanium-based residues) on a hole wall surface. The residue removal properties were evaluated based on the following criteria.

The criteria for determination of the residue removal properties are as follows.
A: As a result of confirmation performed after immersion with SEM under the same conditions, it was confirmed that 95% or more of the residues that were confirmed with SEM before immersion had been removed.
B: As a result of confirmation performed after immersion with SEM under the same conditions, it was confirmed that 85% or more and less than 95% of the residues that were confirmed with SEM before immersion had been removed.
C: As a result of confirmation performed after immersion with SEM under the same conditions, it was confirmed that 80% or more and less than 85% of the residues that were confirmed with SEM before immersion had been removed.
D: As a result of confirmation performed after immersion with SEM under the same conditions, it was confirmed that only less than 80% of the residues that were confirmed with SEM before immersion had been removed.

3-2-2. As a second evaluation method, the residue removability of titanium-based residues was also evaluated by the following method (evaluation based on etching rate).

First, laminates having the respective metal layers (substrates each having a film) were prepared as described below.
A laminate having a metal layer (film thickness: 15 nm) of a Ti oxide film (TiOₓ) formed on a substrate (12-inch silicon substrate) was prepared by the CVD method.
A laminate having a TiN metal layer (film thickness: 15 nm) formed on a substrate (12-inch silicon substrate) was prepared by the CVD method.

Subsequently, the obtained laminates (substrates each having a film) were cut into 2 cm×2 cm in top view to obtain samples for testing (wafer coupons). Then, 80 mL of each of the processing solutions of Examples and Comparative examples was poured into a 100 mL cup. The samples were placed and immersed in the respective processing solutions under the immersion conditions of immersion temperature of 50° C. and predetermined immersion time. The immersion time was 30 minutes for TiOₓ, and 15 minutes for TiN. During the immersion, the processing solutions were stirred at 300 rpm. After the immersion, the samples were taken out from the processing solutions, washed with water at room temperature for 30 seconds, and dried by nitrogen blowing.

Then, by measuring the etching rate (Å/min), the film loss after processing was evaluated. In the case of the metal layers of TiOₓ and TiN, it was determined that the higher the etching rate, the greater the residue removal effect.

### 3-3. Evaluation of Anticorrosion Properties

Samples for testing were prepared in the same manner as in “1-3. Evaluation of anticorrosion properties” in “1. Test 2” above. The anticorrosion properties were evaluated by measuring the etching rate. In the case of the metal layers of SiN and Al₂O₃, it was determined that the lower the etching rate of the metal layers, the more the damage to the metal layers was avoided.

Table 3 and Table 4 indicate the compositions and evaluation results of the processing solutions of Examples. In the tables, “-” means that component was not added.

TABLE 3

| | | Com- | | | | Com- | | | | |
|---|---|---|---|---|---|---|---|---|---|---|
| | | parative | Exam- | Exam- | Exam- | parative | Exam- | Exam- | Exam- | Exam- |
| | | example | ple | ple | ple | example | ple | ple | ple | ple |
| | | 3-1 | 3-1 | 3-2 | 3-3 | 3-2 | 3-4 | 3-5 | 3-6 | 3-7 |
| HF (wt %) | | 0.01 | 0.01 | 0.01 | 0.01 | 0.01 | 0.01 | 0.01 | 0.01 | 0.01 |
| 5MBTA (wt %) | | 0.4 | 0.4 | 0.4 | 0.4 | 0.4 | 0.4 | 0.4 | 0.4 | 0.4 |
| HG (wt %) | | 89.94 | 90 | 90 | 90 | 90 | 90 | 90 | 90 | 90 |
| KOH (wt %) | | — | 0.015 | 0.03 | 0.075 | — | 0.008 | 0.015 | 0.03 | 0.075 |
| HCl (wt %) | | 0.0023 | 0.01 | 0.02 | 0.049 | — | — | — | — | — |
| MSA (wt %) | | — | — | — | — | 0.004 | 0.013 | 0.026 | 0.052 | 0.13 |
| DIW (wt %) | | 9.6477 | 9.565 | 9.54 | 9.466 | 9.586 | 9.569 | 9.549 | 9.508 | 9.385 |
| pH | | 3.3 | 3.3 | 3.3 | 3.3 | 3.3 | 3.3 | 3.3 | 3.3 | 3.3 |
| Ti residue removability | 58° C.-4 min | D | B | C | A | D | C | B | B | B |
| Etching rate | TiOx | 0.3 | 0.5 | 0.5 | 0.5 | 0.3 | 0.4 | 0.3 | 0.3 | 0.4 |
| [Å/min] | TiN | 2.6 | 2.3 | 1.8 | 1.4 | 2.5 | 2.6 | 2.2 | 1.8 | 1.5 |
| | SiN | 0.3 | 1.5 | 2.8 | 2.8 | 0.3 | 1.2 | 1.3 | 1.6 | 1.9 |
| | Al₂O₃ | 17.2 | 21.6 | 36.7 | 43.8 | 25.2 | 14.5 | 35.8 | 19.1 | 27.8 |

TABLE 4

| | | Comparative | Comparative | | | | |
|---|---|---|---|---|---|---|---|
| | | example | example | Example | Example | Example | Example |
| | | 4-1 | 4-2 | 4-1 | 4-2 | 4-3 | 4-4 |
| HF (wt %) | | 0.01 | 0.01 | 0.01 | 0.01 | 0.01 | 0.01 |
| 5MBTA (wt %) | | 0.4 | 0.4 | 0.4 | 0.4 | 0.4 | 0.4 |
| HG (wt %) | | — | 90 | 90 | 95 | 90 | 95 |
| KCl (wt %) | | — | — | 0.0041 | 0.0041 | 0.02 | 0.02 |
| DIW (wt %) | | 99.59 | 9.59 | 9.59 | 4.59 | 9.57 | 4.57 |
| pH | | 2.995 | 4.147 | 3.518 | 3.074 | 3.364 | 2.714 |
| Ti residue | 58° C.~5 min | A | D | A | B | A | B |
| removability | | | | | | | |
| Etching rate | Al₂O₃ | 195 | 18.1 | 10.3 | 12.1 | 41.8 | 17.6 |
| [Å /min] | | | | | | | |

HF: hydrogen fluoride,
5MBTA: 5-methyl-1H-benzotriazole,
HG: hexylene glycol,
KOH: potassium hydroxide,
KCl: potassium chloride,
HCl: hydrogen chloride,
MSA: methanesulfonic acid,
DIW: deionized water

From the above, it was at least confirmed that the processing solutions according to Examples can efficiently remove titanium-based residues and are excellent in anticorrosion properties. Such processing solutions can be suitably used in a method for cleaning a semiconductor substrate and in a method for manufacturing a semiconductor.

The present application claims priority to U.S. Provisional application No. 63/557,127, filed with the United States Patent and Trademark Office on Feb. 23, 2024, the entire content of which is incorporated herein by reference.
10: Substrate
20: Metal wiring layer
30: Etching stop layer
40: Interlayer insulating film
50: Hard mask layer (HM layer)
60: Dry etching residue
100: Semiconductor element

1. A processing solution, comprising:
(A) a compound capable of releasing a fluoride ion;
(B) at least one selected from the group consisting of an ion of an alkali metal, an ion of an alkaline earth metal, and an ion of an element in Group III of the periodic table; and
(C) an organic solvent.

2. The processing solution according to claim 1,
wherein a concentration of the component (B) is from 0.0005 to 0.5% by mass.

3. The processing solution according to claim 1, further comprising:
(D) an anticorrosive agent.

4. The processing solution according to claim 1, further comprising:
(E) water.

5. The processing solution according to claim 3, comprising as the anticorrosive agent (D):
a nitrogen-containing heterocyclic compound or a salt thereof.

6. The processing solution according to claim 4, comprising as the organic solvent (C):
at least one selected from the group consisting of an alcohol-based solvent, a glycol ester-based solvent, a sulfoxide-based solvent, a sulfone-based solvent, an amide-based solvent, a lactone-based solvent, an imidazolidinone-based solvent, a nitrile-based solvent, a ketone-based solvent, an ether-based solvent, an ester-based solvent, a pyrrolidone-based solvent, and a urea-based solvent.

7. The processing solution according to claim 1,
wherein a content of the organic solvent (C) is from 0.1 to 99.999% by mass.

8. The processing solution according to claim 1,
wherein a pH of the processing solution is from 2 to 6.

9. The processing solution according to claim 1,
wherein the processing solution is a processing solution for a semiconductor substrate,
the semiconductor substrate comprises a substrate and a film formed on the substrate, and
the film comprises at least one selected from the group consisting of a silicon atom, a titanium atom, a cobalt atom, and an aluminum atom.

10. A method for processing a semiconductor substrate, the semiconductor substrate comprising a protective film, the method comprising:
a step for removing an impurity from the semiconductor substrate by bringing the processing solution according to claim 1 into contact with the protective film.

11. A method for manufacturing a semiconductor, comprising:
a step for preparing a semiconductor substrate comprising a substrate and a protective film provided on the substrate,
a step for performing etching using the protective film, and
a step for removing an impurity from the semiconductor substrate by bringing the processing solution according to claim 1 into contact with the semiconductor substrate after the etching.
